(19) United States
(12) Patent Application Publication
(10) Pub. No.: US 2011/0147942 A1
(43) Pub. Date: Jun. 23, 2011

(54) METHOD OF MANUFACTURING SEMICONDUCTOR MEMORY DEVICE AND SEMICONDUCTOR MEMORY DEVICE

(75) Inventors: Katsunori YAHASHI, Yokkaichi-shi (JP); Takuji Kuniya, Yokkaichi-shi (JP); Takaya Matsushita, Yokkaichi-shi (JP); Murato Kawai, Yokkaichi-shi (JP); Shuichi Taniguchi, Oita-shi (JP)

(73) Assignee: KABUSHIKI KAISHA TOSHIBA, Tokyo (JP)

(21) Appl. No.: 12/838,960

(22) Filed: Jul. 19, 2010

(30) Foreign Application Priority Data
Dec. 18, 2009 (JP) 2009-287323

(51) Int. Cl. H01L 23/52; H01L 21/768

(52) U.S. Cl. 257/773; 438/622; 257/E23.141; 257/E21.575

(57) ABSTRACT

A method of manufacturing a semiconductor memory device of an embodiment includes: after forming a first interconnection layer and a memory cell layer above a semiconductor substrate, forming first lines by forming first grooves extending in first direction; forming a thin film on the side walls of the first grooves; forming a stack structure by filling an interlayer insulating film in the first grooves; forming a second interconnection layer above the stack structure; forming second lines by forming second grooves extending in second direction; removing the thin film exposed at bottom of the second grooves; and forming columnar memory cells by removing the memory cell layer exposed at bottom of the second grooves. The thin film has higher etching rate than the interlayer insulating film, and is removed prior to portions of the memory cell layer adjoining the thin film.

### CROSS REFERENCE TO RELATED APPLICATIONS

This application is based on and claims the benefit of priority from prior Japanese Patent Application No. 2009-287323, filed on Dec. 18, 2009, the entire contents of which are incorporated herein by reference.

### BACKGROUND

1. Field

Embodiments described herein relate generally to a method of manufacturing a semiconductor memory device and a semiconductor memory device.

2. Description of the Related Art

Conventionally, as electrically rewritable nonvolatile memories, flash memories are known that includes a memory cell array configured by NAND connection or NOR connection of memory cells each having a floating gate structure. Also, ferroelectric memories are known as memories that are nonvolatile and compatible with fast random access.

Meanwhile, resistance varying memories using a variable resistance element in each memory cell are proposed as a technique for enabling greater miniaturization of memory cells. Specifically, the followings are known: a phase-change memory element having a resistance varied by phase changes of a chalcogenide compound between a crystallized state and an amorphous state; an MRAM element utilizing resistance changes caused by tunnel magnetoresistance effect; a memory element formed of a polymer ferroelectric RAM (PFRAM) including a resistor element made of a conductive polymer; a ReRAM element having a resistance varied by application of electric pulses, etc.

In the resistance varying memories, memory cells can be formed as a cross-point type memory cell that is a series circuit of a Schottky diode instead of a transistor and a variable resistance element. Therefore, these memories can be easily stacked to a three-dimensional structure and hence are advantageous for greater integration.

When manufacturing such cross-point type memory cells according to a self-aligning fashion that makes the cells align with interconnection patterns, a grooving process of forming a certain pattern of lines and spaces (hereinafter referred to as “L/S”) extending in a first direction is firstly applied to a stack structure formed of a memory cell layer and an underlying interconnection layer to form a plurality of first grooves in the stack structure and divide the stack structure along the first grooves. Then, an interlayer insulating film made of SiO₂ is filled in the first grooves, and an overlying interconnection layer is formed on the filled stack structure. Then, a grooving process of forming a certain pattern of L/S extending in a second direction perpendicular to the first direction is applied to the stack structure filled with the interlayer insulating film and capped with the overlying interconnection layer to form a plurality of second grooves deep to the top surface of the underlying interconnection layer. This completes cross-point type memory cells between the perpendicular interconnection lines.

However, this manufacturing method cannot expect an etching mask to sustain as long as the formation of the second grooves and might have the overlying interconnection layer, etc. etched. A conceivable measure for this is to use an etching mask having a sufficient film thickness. However, in this case, the etching mask might become unstable and fall over, and this tendency becomes more apparent as miniaturization of patterns proceeds. Further, it is difficult to achieve an etching selectivity of 1:1 between the material of the memory cell layer and SiO₂ from which the interlayer insulating film is made. Therefore, when forming the second grooves, the memory cell layer is etched faster than the interlayer insulating film, and the remaining interlayer insulating film hinders as a mask to make the memory cell material remain at the lower portion of the side walls of the interlayer insulating film. This might lead to a short-circuiting between adjoining memory cells.

### BRIEF DESCRIPTION OF THE DRAWINGS

FIG. 1 is a perspective diagram showing a part of a cross-point type cell array of a semiconductor memory according to a first embodiment.

FIG. 2A is a cross section of one memory cell taken along a line I-I′ of FIG. 1 and seen in the direction of the arrows.

FIG. 2B is an equivalent circuit diagram of the memory cell shown in FIG. 2A.

FIG. 3 is a diagram showing an example of a ReRAM of the semiconductor memory according to the first embodiment.

FIG. 4A is a perspective diagram showing a part of the memory cell array of the semiconductor memory according to the first embodiment.

FIG. 4B is a diagram showing word lines, bit lines, and memory cells of FIG. 4A.

FIGS. 5A to 5Q are perspective diagrams showing a process of forming the memory cell array of the semiconductor memory according to the first embodiment in sequence.

FIG. 6 is a perspective diagram showing a part of a memory cell array of a semiconductor memory according to a second embodiment.

FIGS. 7A to 7E are perspective diagrams showing a process of forming the memory cell array of the semiconductor memory according to the second embodiment in sequence.

FIG. 8 is a perspective diagram showing a part of a memory cell array of a semiconductor memory according to a third embodiment.

FIGS. 9A to 9D are perspective diagrams showing a process of forming the memory cell array of the semiconductor memory according to the third embodiment in sequence.

FIGS. 10 to 13 are diagrams for explaining problems in methods of manufacturing a semiconductor memory according to comparative examples.

### DETAILED DESCRIPTION

A method of manufacturing a semiconductor memory device according to an embodiment includes: forming a first interconnection layer above a semiconductor substrate; forming a first memory cell layer to constitute first memory cells above the first interconnection layer; after forming the first memory cell layer, forming first lines by forming first grooves deep to the bottom of the first interconnection layer and extending in a first direction; forming a first thin film on the side walls of the first grooves; forming a first stack structure by filling a first interlayer insulating film in the first grooves having the first thin film formed thereon; forming a second interconnection layer above the first stack structure; forming second lines by forming second grooves deep to the bottom of the second interconnection layer and extending in a second direction intersecting with the first direction; removing the first thin film exposed at the bottom of the second grooves; and forming the first memory cells having a columnar shape by removing the first memory cell layer exposed at the bottom of the second grooves. The first thin film has a higher etching rate than that of the first interlayer insulating film, and is removed prior to removing those portions of the first memory cell layer that adjoin the first thin film.

A semiconductor memory device according to an embodiment includes: a plurality of first lines extending in a first direction; a plurality of second lines extending in a second direction intersecting with the first direction; a plurality of columnar memory cells connected between the first and second lines at the intersections of the first and second lines; and an interlayer insulating film provided between adjoining ones of the memory cells. A space is provided between each of the memory cells and the interlayer insulating film.

The embodiments described above will now be explained with reference to the drawings.

### FIRST EMBODIMENT

### Structure of Memory Cell Array

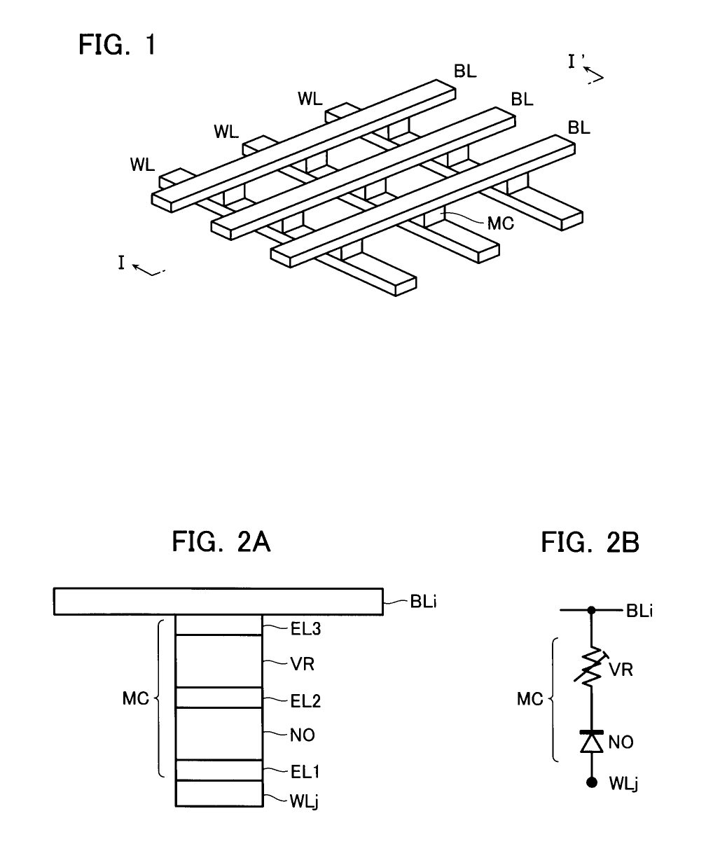

FIG. 1 is a perspective diagram showing a part of a cross-point type cell array of a semiconductor memory according to a first embodiment. FIG. 2A is a cross section of one memory cell taken along the line I-I′ of FIG. 1 and seen in the direction of the arrows. FIG. 2B is an equivalent circuit diagram of the memory cell.

In the cross-point type memory cell array, word lines WL or a plurality of first lines are provided in parallel, bit lines BL or a plurality of second lines are provided in parallel to intersect the word lines WL, and memory cells MC are provided at the intersections of these lines as sandwiched between these lines. The word lines WL and bit lines BL are preferably made of a material that is heat-resistant and has a low resistance, and may be made of, for example, W, WSi, NiSi, CoSi, etc.

As shown in FIG. 2A and FIG. 2B, a memory cell MC is composed of a variable resistance element VR and a non-ohmic element NO which are connected in series.

The variable resistance element VR can vary its resistance via a current, heat, chemical energy, etc. upon voltage application, and includes electrodes EL2 and EL3 which are provided on the top and bottom to function as a barrier metal and an adhesive layer. The electrode material may be Pt, Au, Ag, TiAlN, SrRuO, Ru, RuN, Ir, Co, Ti, TiN, TaN, LaNiO, Al, PtIrOₓ, PtRhOₓ, Rh/TaAlN, etc. The element may also include a metal film which provides a uniform orientation. The element may also specially include a buffer layer, a barrier metal layer, an adhesive layer, etc.

The variable resistance element VR may be a type (PCRAM) that varies its resistance through phase change between a crystallized state and a non-crystallized state as in chalcogenide, etc., a type (CBRAM) that varies its resistance by forming a bridge (a conducting bridge) between electrodes by precipitating metal cations and destroying the bridge by ionizing the precipitated metal, a type (ReRAM) that, though not based on a fixed theory, varies its resistance upon voltage or current application (when classified based on the factor of resistance change, this type is roughly classified into those that cause a resistance change depending on presence or absence of charges trapped in a charge trap existing at an electrode interface and those that cause a resistance change depending on presence or absence of a conducting path due to oxygen loss, etc.), etc.

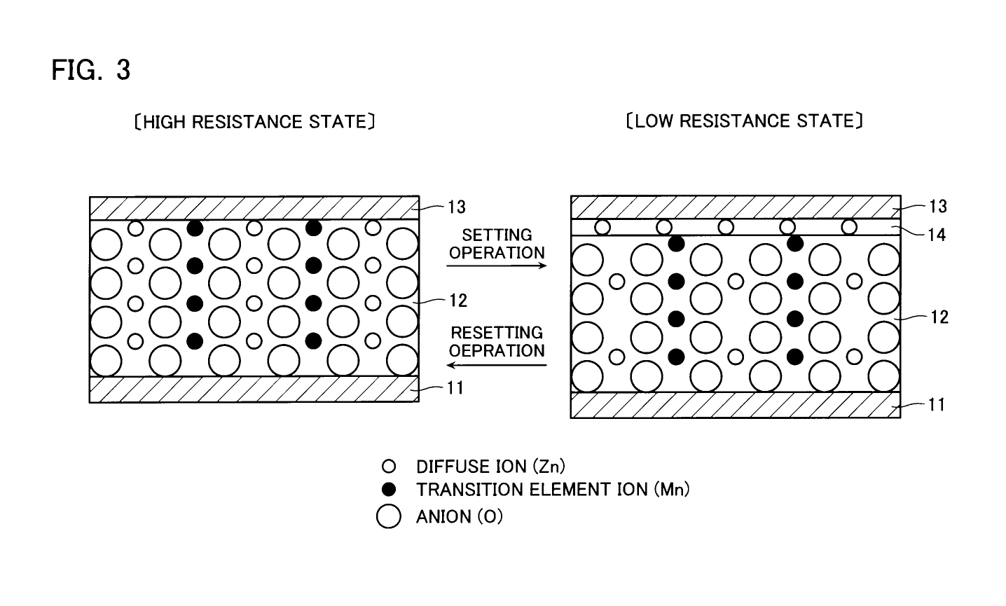

FIG. 3 is a diagram showing an example of a ReRAM. The ReRAM element shown in FIG. 3 is composed of electrode layers 11 and 13, and a recording layer 12 positioned between them. The recording layer 12 is made of a complex compound containing at least two kinds of cationic elements. At least one kind of the cationic elements should be a transition element having a d-orbital incompletely filled with electrons, and the shortest distance between adjoining cationic elements should be 0.32 nm or shorter. Specifically, the recording layer 12 is made of a material which is represented by a chemical formula AₓM_{y}X_{z} (where A and M are different elements), and which has a crystalline structure such as a spinel structure (AM₂O₄), an ilmenite structure (AMO₃), a delafossite structure (AMO₂), a LiMoN₂ structure (AMN₂), a wolframite structure (AMO₄), an olivine structure (A₂MO₄), a hollandite structure (AₓMO₂), a ramsdellite structure (AₓMO₂), a perovskite structure (AMO₃), etc.

In the example of FIG. 3, A is Zn, M is Mn, and X is O. Small white circles in the recording layer 12 represent diffuse ions (Zn), large white circles represent anions (O), and small black circles represent transition element ions (Mn). The recording layer 12 is in a high resistance state initially, but when a negative voltage is applied to the electrode layer 13 while the electrode layer 11 is set at a fixed potential, some diffuse ions in the recording layer 12 move toward the electrode layer 13, and hence diffuse ions in the recording layer 12 are reduced relative to anions. The diffuse ions having moved toward the electrode layer 13 receive electrons from the electrode layer 13 and precipitate as a metal, forming a metal layer 14. In the recording layer 12, anions have become excessive, and this leads to an increase of the valence of the transition element ions in the recording layer 12. Hence, the recording layer 12 becomes electron-conductive through carrier injection and enters a set state. To reproduce the data requires causing such a minute current as would not induce a resistance change of the material of the recording layer 12 to flow through the recording layer 12. To reset the programmed state (low resistance state) to the initial state (high resistance state) requires, for example, causing a large current to flow through the recording layer 12 for a sufficient time to cause Joule heating and promote the oxidoreduction reaction of the recording layer 12. Applying an electric field in a direction opposite to the setting operation can also achieve resetting.

The non-ohmic element NO is constituted by a diode such as a Schottky diode, a PN junction diode, a PIN diode, etc., an MIM (Metal-Insulator-Metal) structure, an SIS (Silicon-Insulator-Silicon) structure, or the like. The non-ohmic element NO may also include electrodes EL1 and EL2 that form a barrier metal layer and an adhesive layer. The electrode material may be Pt, Au, Ag, TiAlN, SrRuO, Ru, RuN, Ir, Co, Ti, TiN, TaN, LaNiO, Al, PtIrOₓ, PtRhOₓ, Rh/TaAlN, etc. When a diode is used, a unipolar operation is available based on the characteristic of the diode. When an MIM structure, an SIS structure, or the like is used, a bipolar operation is available. The arrangement of the non-ohmic element NO and the variable resistance element VR may be reversed from FIG. 2A vertically, or the polarities of the non-ohmic element NO may be reversed vertically.

In the semiconductor memory according to the present embodiment, a setting voltage pulse, a resetting voltage pulse, and a reading voltage are applied to a selected memory cell MC in a setting operation, a resetting operation, and a data reading operation, respectively. That is, an “H” level is supplied to a word line WL connected to the selected memory cell MC, an “L” level is supplied to a bit line BL connected to the selected memory cell MC, an “L” level is supplied to the other word lines WL, and an “H” level is supplied to the other bit lines BL. As a result, a voltage necessary for data setting, resetting, or reading is applied to the selected memory cell MC, and data setting, resetting, or reading on the selected memory cell MC is effected. Since a reverse bias voltage or 0V is applied to the memory cells MC other than the selected memory cell MC, no current flows through these memory cells MC.

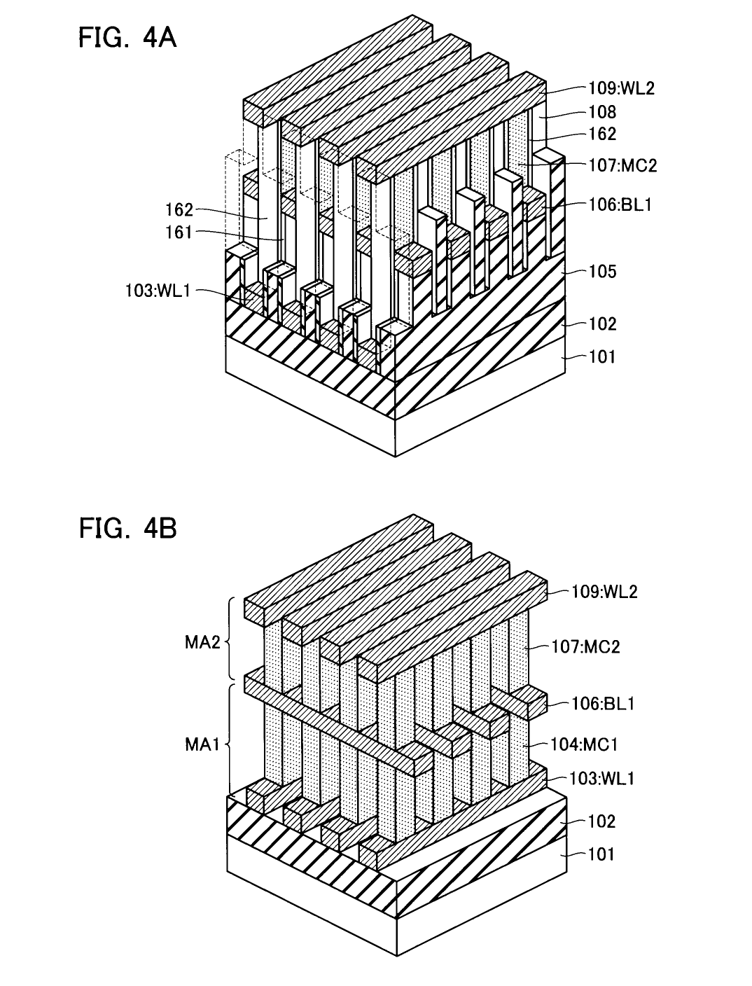

FIG. 4A is a perspective diagram showing a part of the memory cell array of the semiconductor memory according to the present embodiment. FIG. 4B is a diagram which gives a clearer view of the arrangement of the word lines WL, the bit lines BL, and the memory cells MC in the memory cell array shown in FIG. 4A.

This memory cell array is a two-layered memory cell array including cell array layers MA1 and MA2 stacked on a semiconductor substrate 101. Bit lines 106 are shared between the upper and lower cell array layers MA1 and MA2.

Impurity diffusion layers and gate electrodes of transistors that constitute unillustrated peripheral circuits are formed on the semiconductor substrate 101. An insulating layer 102 made of SiO₂ is stacked on the peripheral circuits. A plurality of word lines WL1 (103) extending in a first direction are formed on the insulating layer 102 (hereinafter, the first direction will be referred to as “word line direction”). A plurality of first memory cells MC1 (104) are formed on the word lines WL1. A plurality of bit lines BL1 (106) extending in a second direction perpendicular to the word line direction are formed on the memory cells MC1 (104) (hereinafter, the second direction will be referred to as “bit line direction”). The cell array layer MA1 is composed of the word lines WL1, the memory cells MC1, and the bit lines BL1. A plurality of second memory cells MC2 (107) are formed on the bit lines BL1. A plurality of word lines WL2 (109) extending in the word line direction are formed on the memory cells MC2. The cell array layer MA2 is composed of the bit lines BL1, the memory cells MC2, and the word lines WL2. A first interlayer insulating film 105 made of SiO₂ is filled between each two memory cells MC adjoining in the bit line direction, and a first thin film 161 made of SiN is interposed between each memory cell MC and the interlayer insulating film 105. Likewise, a second interlayer insulating film 108 made of SiO₂ is filled between each two memory cells MC adjoining in the word line direction, and a second thin film 162 made of SiN is interposed between each memory cell MC and the interlayer insulating film 108.

While the memory cell array shown in FIG. 4A and FIG. 4B has a two-layered structure, it is possible to form a memory cell array including an arbitrary number of layers, by repetitively stacking the structure from the memory cells MC1 to the bit lines BL1 and the structure from the memory cells MC2 to the word lines WL2 alternately above the word lines WL2.

### Method of Manufacturing Memory Cell Array

Next, a method of manufacturing the two-layered memory cell array shown in FIG. 4A and FIG. 4B will be explained.

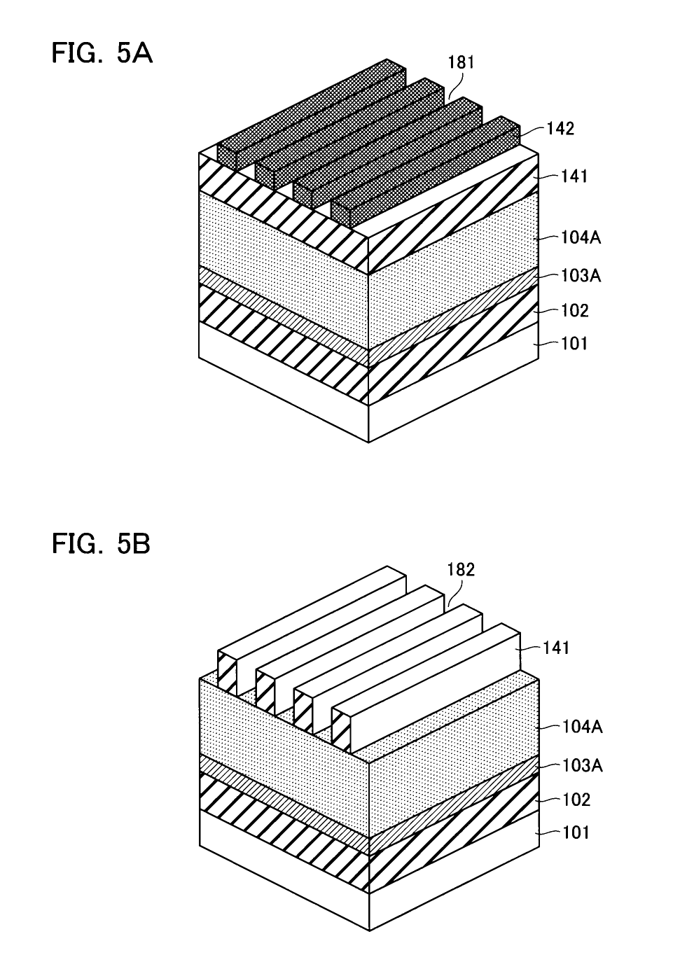

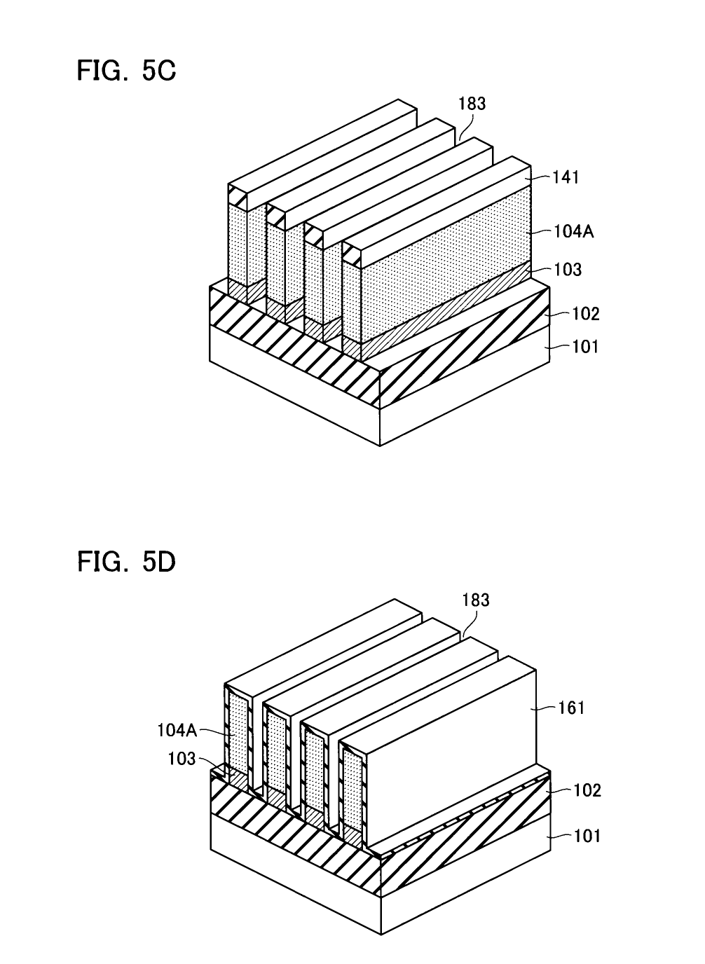

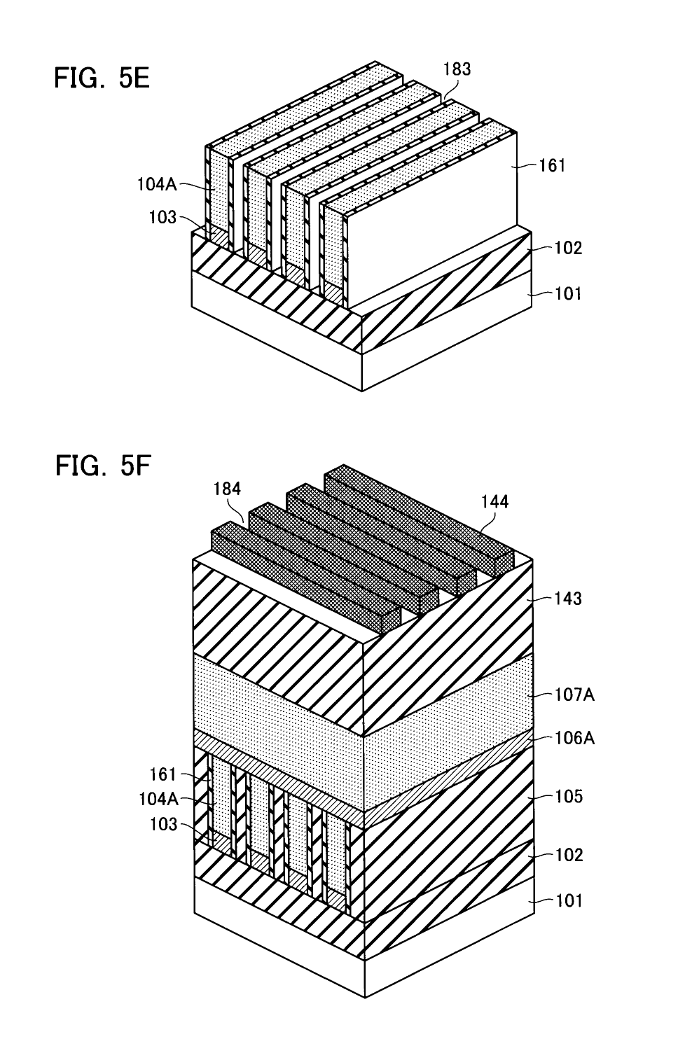

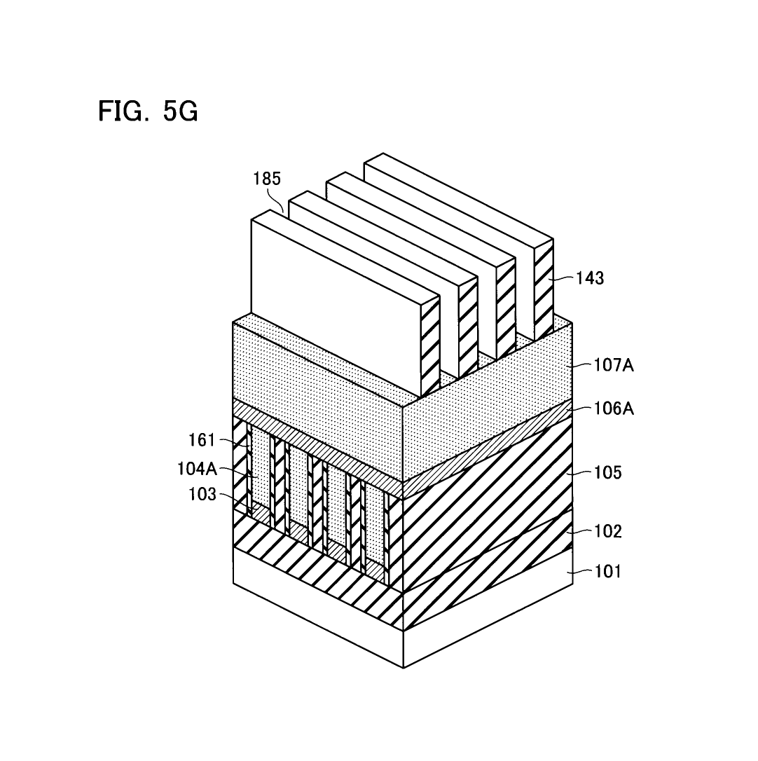

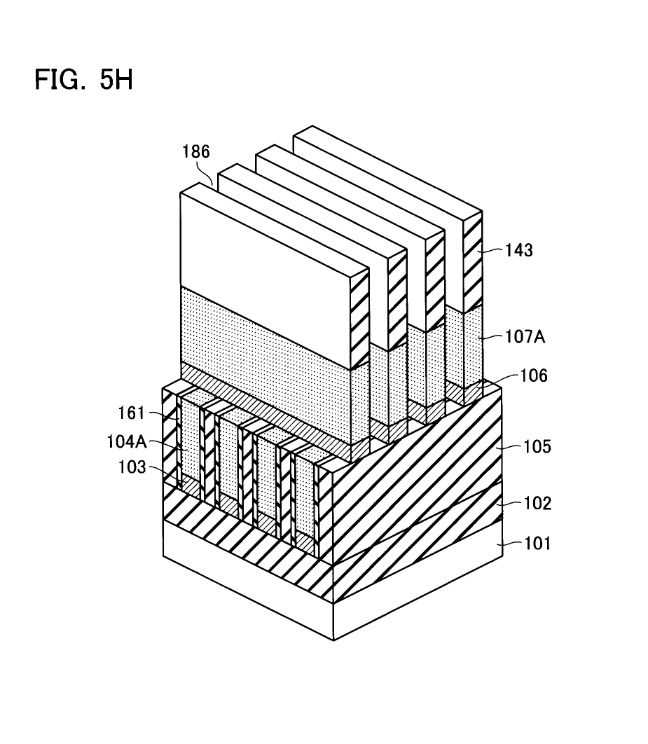

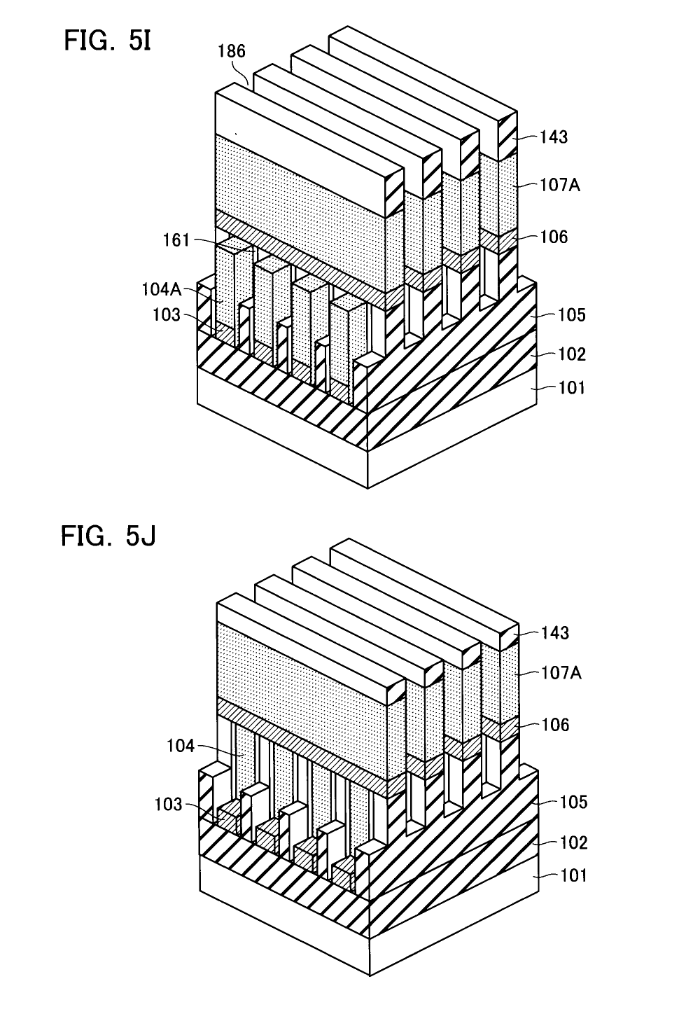

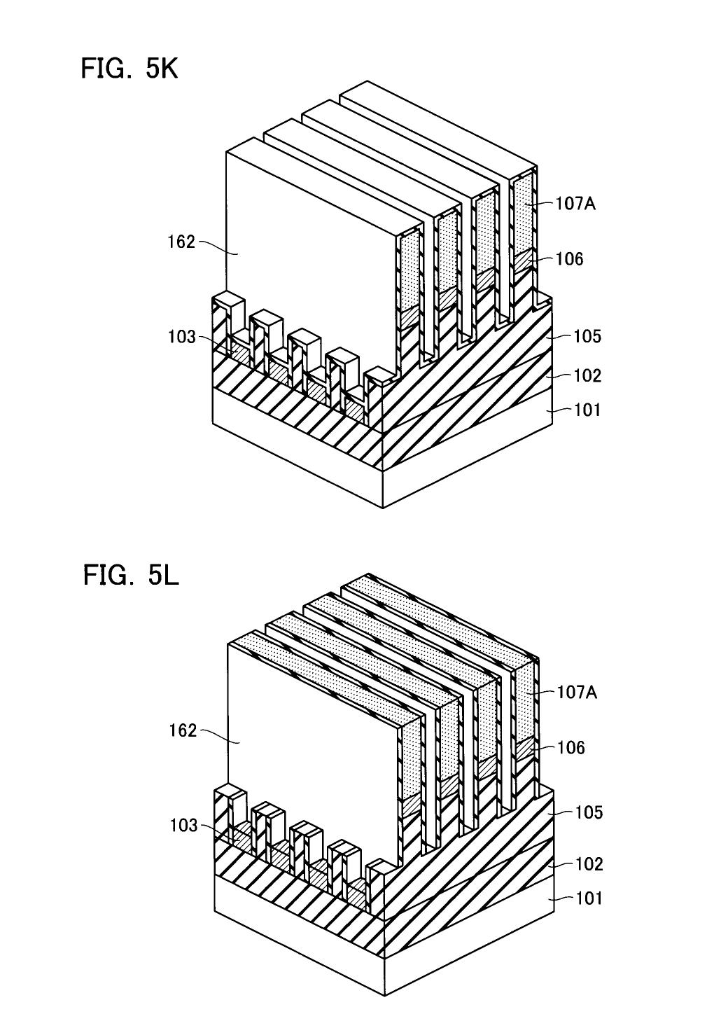

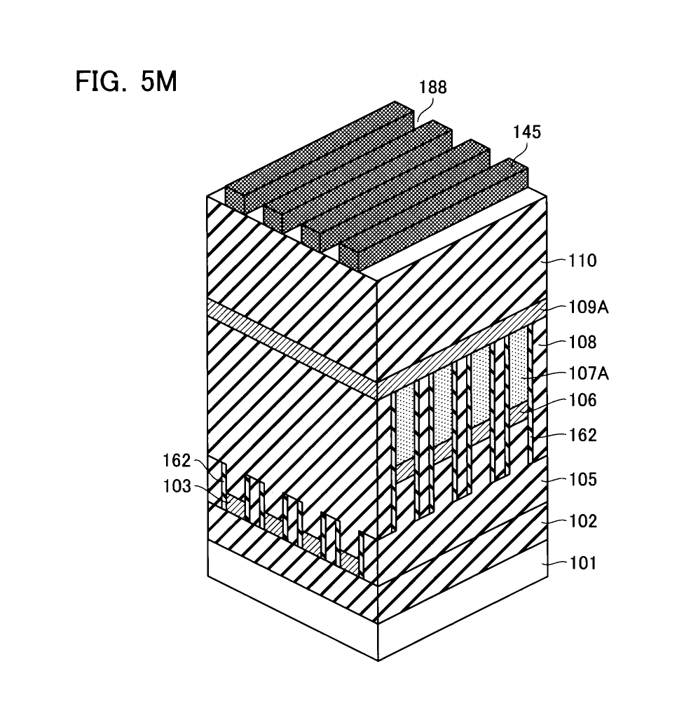

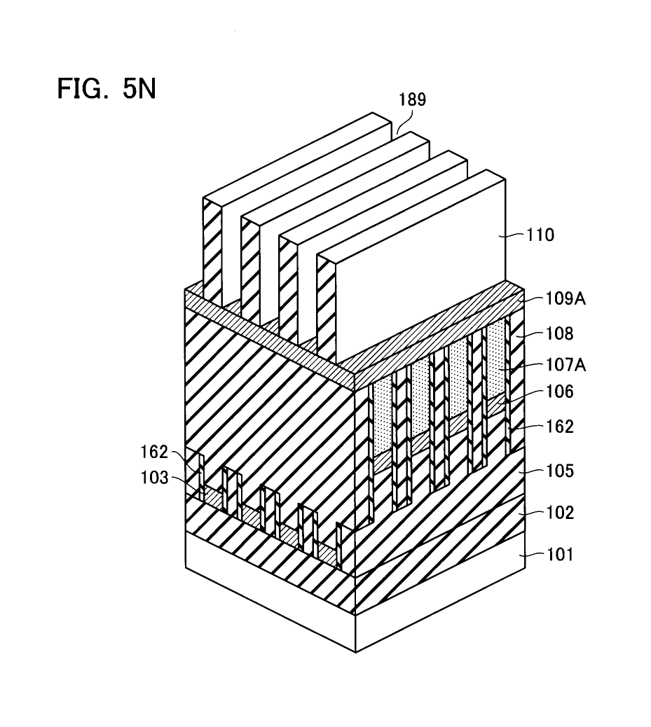

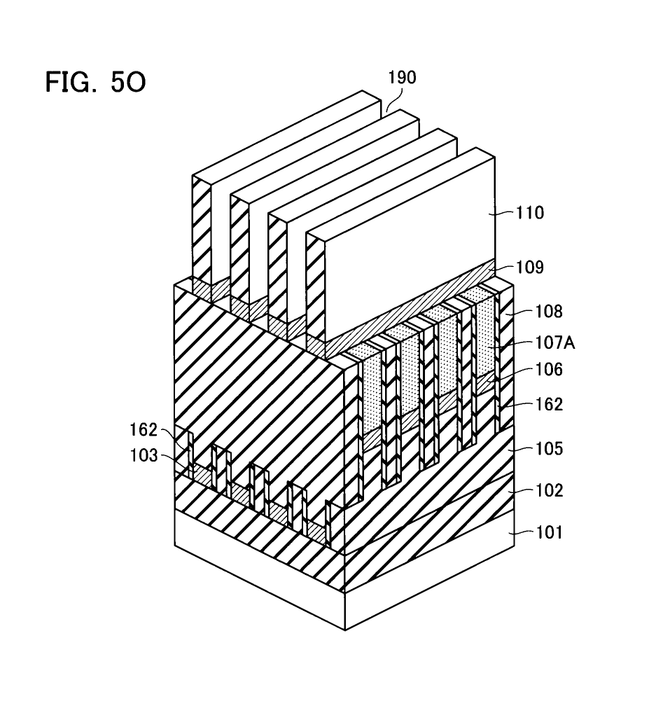

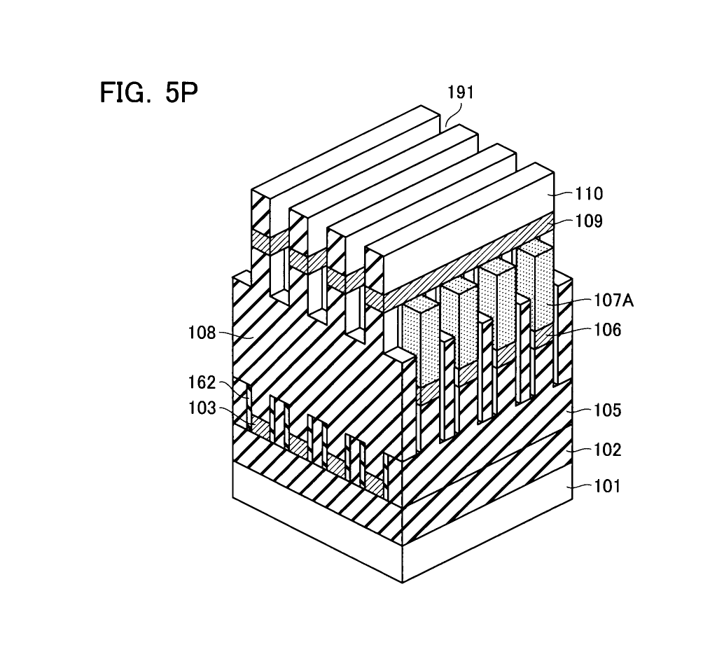

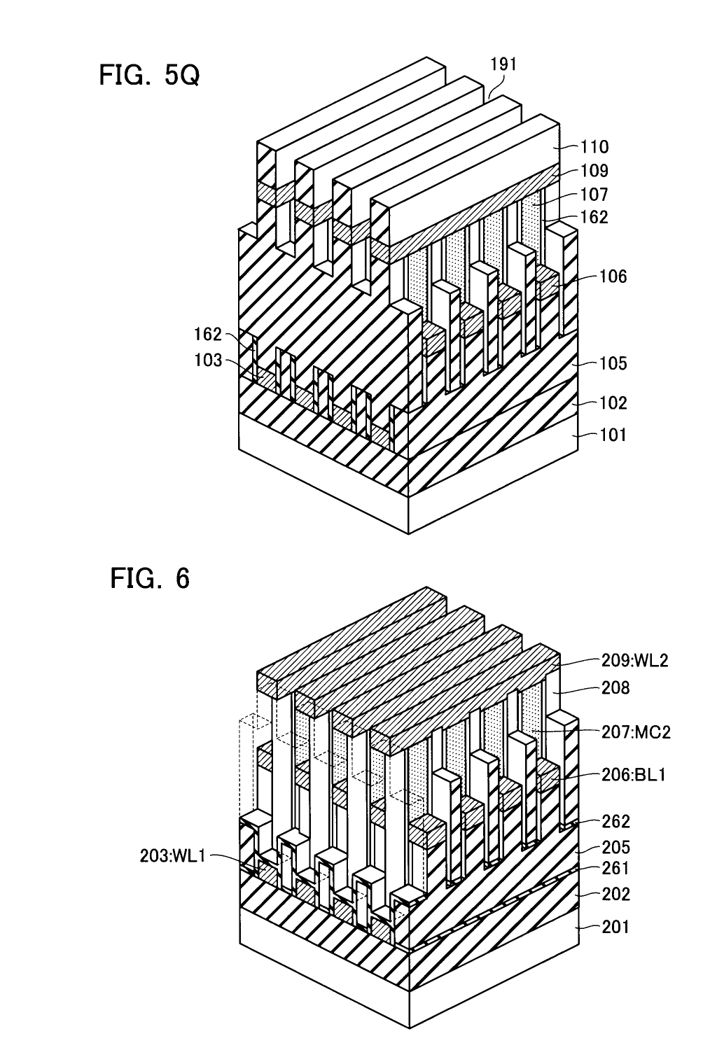

FIG. 5A to FIG. 5Q are perspective diagrams showing a process of forming the memory cell array in sequence.

First, an FEOL (Front End Of Line) process is executed to form transistors, etc. which constitute peripheral circuits on the semiconductor substrate 101, and an insulating layer 102 made of SiO₂ is deposited on the peripheral circuits. Here, vias (unillustrated) are also formed.

Next, as shown in FIG. 5A, a first interconnection layer 103A to become the word lines WL1, a first memory cell layer 104A to become the memory cells MC1, and an etching mask 141 made of SiO₂ to be used in a later step of processing the interconnection layer 103A and the memory cell layer 104A in the word line direction are sequentially stacked on the insulating layer 102, and a photo-resist 142 having a certain L/S pattern including a plurality of grooves 181 extending in the word line direction is formed on the etching mask 141.

Then, as shown in FIG. 5B, a plurality of grooves 182 extending in the word line direction are formed in the etching mask 141 by a photo etching process using the photo-resist 142 as a mask.

Then, as shown in FIG. 5C, a plurality of first grooves 183 which reach the bottom surface of the interconnection layer 103A are formed by anisotropic etching such as RIE (Reactive Ion Etching), etc. using the etching mask 141 as a mask. As a result, a plurality of word lines WL1 (103) are formed and the memory cell layer 104A is divided along the first grooves 183. After this, the etching mask 141 is stripped.

Then, as shown in FIG. 5D, a liner-like first thin film 161 is formed on the side walls and a bottom surface of the first grooves 183 and on the top surfaces of the memory cell layer 104A. The thin film 161 is made of a material having a higher etching rate than that of the material of a first interlayer insulating film 105 to be formed in a later step. Specifically, SiN, SiO₂, Al₂O₃, CVD-C, SiBN, SiC, BN, etc., and Low-k materials such as SiOC, etc. can be used as the material of the thin film 161. When the material of the interlayer insulating film 105 is, for example, SiO₂, SiN can be used as the material of the thin film 161. When a porous film is used as the thin film 161, a high insulating performance can be achieved. For example, when an organic film containing C (carbon) is used as the thin film 161, it is desirable that the thin film 161 be a porous film.

Then, as shown in FIG. 5E, the thin film 161 is removed by anisotropic etching in a manner that the portions of the thin film 161 that are formed on the side walls of the first grooves 183 remain.

Then, as shown in FIG. 5F, a first stack structure is formed by filling a first interlayer insulating film 105 made of SiO₂ in the first grooves 183, and then smoothing the top surfaces of the memory cell layer 104A, thin film 161, and interlayer insulating film 105 by CMP (Chemical Mechanical Polish) or the like. After this, a second interconnection layer 106A to become the bit lines BL1, a second memory cell layer 107A to become the second memory cells MC2, and an etching mask 143 made of SiO₂ to be used in later steps of processing the structure from the top surface of the memory cell layer 107A down to the top surface of the word lines 103 in the bit line direction are sequentially stacked on the first stack structure. A photo-resist 144 having a certain L/S pattern including a plurality of grooves 184 extending in the bit line direction is formed on the etching mask 143.

Then, as shown in FIG. 5G, a plurality of grooves 185 extending in the bit line direction are formed in the etching mask 143 by a photo etching process using the photo-resist 144 as a mask.

Then, as shown in FIG. 5H, second grooves 186 which reach the bottom surface of the interconnection layer 106A are formed by anisotropic etching such as RIE, etc. using the etching mask 143 as a mask. As a result, a plurality of bit lines BL1 are formed and the memory cell layer 107A is divided along the second grooves 186.

Then, as shown in FIG. 5I, the thin film 161 is removed selectively by anisotropic etching such as RIE, etc. using the etching mask 143 as a mask. At this time, the top of the interlayer insulating film 105 is lowered. In this etching step, it is only desired that the first thin film 161 be removed in order that no residue of the first thin film 161 may exist when etching the memory cell layer 104A in the next step, and it is hence allowed that the interlayer insulating film 105 remain.

Then, as shown in FIG. 5J, the memory cell layer 104A is removed selectively by anisotropic etching such as RIE, etc. using the etching mask 143 as a mask. As a result, columnar memory cells MC1 (104) are formed at the intersections of the word lines WL1 (103) and the bit lines BL1 (106). After this, the etching mask 143 is stripped.

Then, as shown in FIG. 5K, a liner-like second thin film 162 is formed on the externally-exposed portions of the insulating layer 102, word lines WL1 (103), first memory cells MC1 (104), first interlayer insulating film 105, bit lines BL1 (106), and second memory cell layer 107A. Like the first thin film 161, the second thin film 162 is made of a material having a higher etching rate than that of the material of a second interlayer insulating film 108 to be formed in a later step.

Next, as shown in FIG. 5L, the thin film 162 is removed by anisotropic etching to an extent that the top surface of the memory cell layer 107A is exposed.

Then, as shown in FIG. 5M, a second stack structure is formed by filling a second interlayer insulating film 108 made of SiO₂ in the second grooves 186 and smoothing the top surfaces of the memory cell layer 107A, thin film 162, and interlayer insulating film 108 by CMP or the like. After this, a third interconnection layer 109A to become the word lines WL2 and an insulating layer 110 made of SiO₂ to be used in later steps of processing the structure from the top surface of the interconnection layer 109A to the top surface of the bit lines BL1 (106) in the word line direction are sequentially stacked on the second stack structure. A photo-resist 145 having a certain L/S pattern including a plurality of grooves 188 extending in the word line direction is formed on the insulating layer 110.

Then, as shown in FIG. 5N, a plurality of grooves 189 extending in the word line direction are formed in the insulating layer 110 through the photo-resist 145 by a photo etching process.

Then, as shown in FIG. 50, third grooves 190 which reach the bottom surface of the interconnection layer 109A are formed by anisotropic etching such as RIE, etc. using the insulating layer 110 as a mask. As a result, a plurality of word lines WL2 (109) are formed.

Then, as shown in FIG. 5P, the thin film 162 is removed selectively by anisotropic etching such as RIE, etc. using the insulating layer 110 as a mask. In this etching step, it is only desired that the second thin film 162 be removed in order that no residue of the second thin film 162 may exist when etching the memory cell layer 107A in the next step, and it is hence allowed that the interlayer insulating film 108 remain.

Then, as shown in FIG. 5Q, the memory cell layer 107A is removed selectively by anisotropic etching such as RIE, etc. using the insulating layer 110 as a mask. As a result, columnar memory cells MC2 (107) are formed at the intersections of the bit lines BL1 (106) and the word lines WL2 (109), and the memory cell array shown in FIG. 4A and FIG. 4B is formed.

Lastly, the memory cell array according to the present embodiment is completed by filling an interlayer insulating film (unillustrated) in the grooves 191 between memory cells MC2 (107) adjoining in the bit line direction.

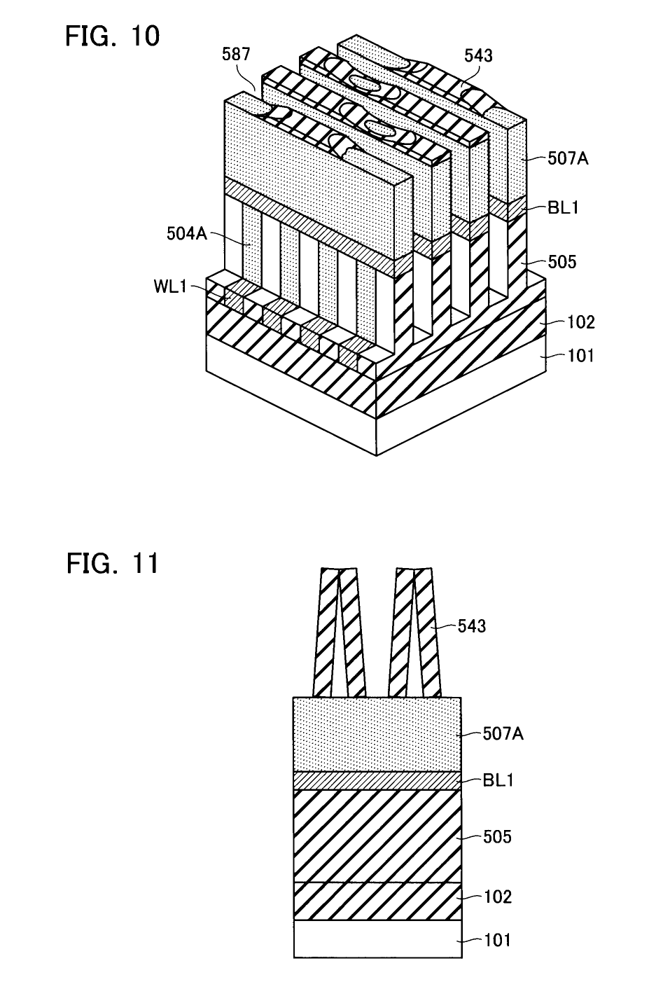

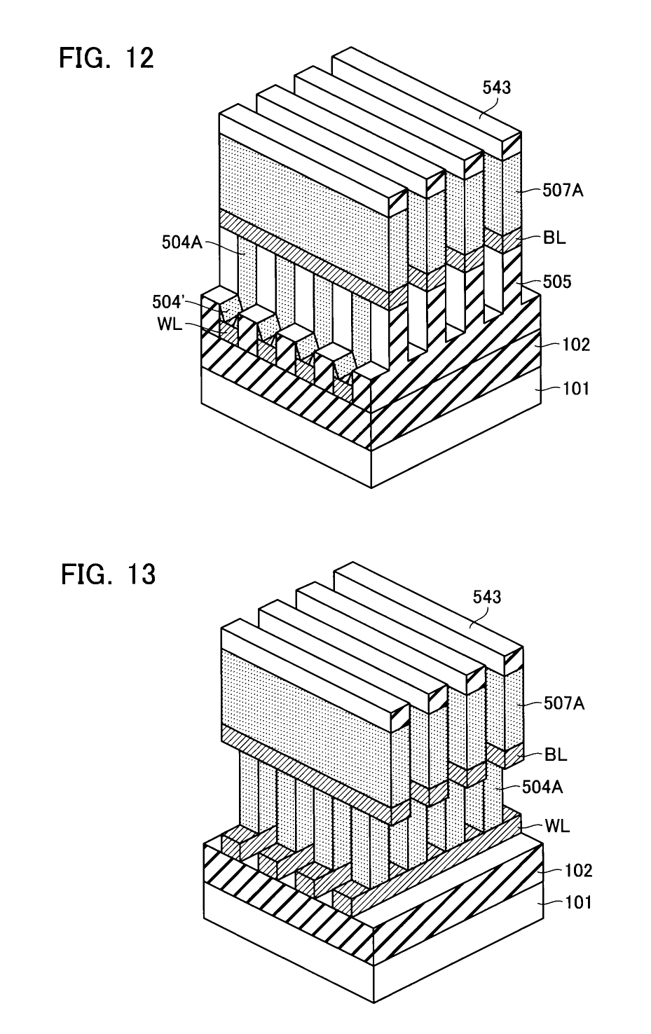

Here, as a comparative example, a process of manufacturing a memory cell array, which does not use the thin films 161 and 162, will be considered with reference to FIG. 10 to FIG. 12. In this case, when forming grooves 587 extending in the bit line direction in a first interlayer insulating film 505 (corresponding to the first interlayer insulating film 105), it is necessary to use an etching mask 543 (corresponding to the etching mask 143) having a sufficient thickness because the etching selectivity of the first interlayer insulating film 505 cannot be increased with respect to the etching mask 543. If the etching mask 543 does not have a sufficient thickness, the mask is used up in the middle of etching and a memory cell layer 507A (corresponding to the second memory cell layer 107A) gets partially lost as shown in FIG. 10. A measure for this might be thickening the etching mask 543. In this case, however, the etching mask 543 might fall over as shown in FIG. 11, which is a problem. Further, because the etching selectivity between the material of a memory cell layer 504A (corresponding to the first memory cell layer 104A) and the material of the interlayer insulating film 505 cannot be 1:1, the interlayer insulating film 505 cannot be sufficiently removed and some residue 504′ of the memory cell material remains on the side walls of the interlayer insulating film 505, leading to a problem that the memory cells MC might be short-circuited. A conceivable measure for this problem may be making the interlayer insulating film 505 from a material which has a higher etching selectivity with respect to the memory cell layer 504A. However, not only will this make it harder to maintain insulating performance, but also spoil physical strength and make manufacturing harder in terms of integration because spaces are produced between adjoining memory cells as shown in FIG. 13.

In this regard, according to the manufacturing method of the present embodiment, which forms the thin films 161 and 162 having a higher etching rate than that of the interlayer insulating films 105 and 108 such that the thin films adjoin the memory cell layers 104A and 107A, the regions which adjoin the memory cell layers 104A and 107A and at which there could occur some residue of the memory cell material can be removed with less mask loss before the removal of the memory cell layers 104A and 107A, which prevents the problems caused in the above comparative example.

According to the present embodiment, it is possible to provide a method of manufacturing a semiconductor memory device which saves etching mask loss and allows no residue to remain that becomes the cause of a short-circuiting between adjoining memory cells, and a semiconductor memory device manufactured by this manufacturing method.

### SECOND EMBODIMENT

### Structure of Memory Cell Array

FIG. 6 is a perspective diagram showing a part of a memory cell array of a semiconductor memory according to a second embodiment. Portions of the second embodiment that correspond to the portions denoted by reference numerals 101 to 186 of the memory cell array of the first embodiment will be denoted by reference numerals 201 to 286, and redundant explanation about such corresponding portions will not be provided.

The present memory cell array differs from the memory cell array according to the first embodiment shown in FIG. 4A and FIG. 4B in that a first thin film 261 is formed also at the bottom of a first interlayer insulating film 205, and that a second thin film 262 is formed also at the bottom of a second interlayer insulating film 208.

### Method of Manufacturing Memory Cell Array

Next, a method of manufacturing the memory cell array having a two-layered structure shown in FIG. 6 will be explained.

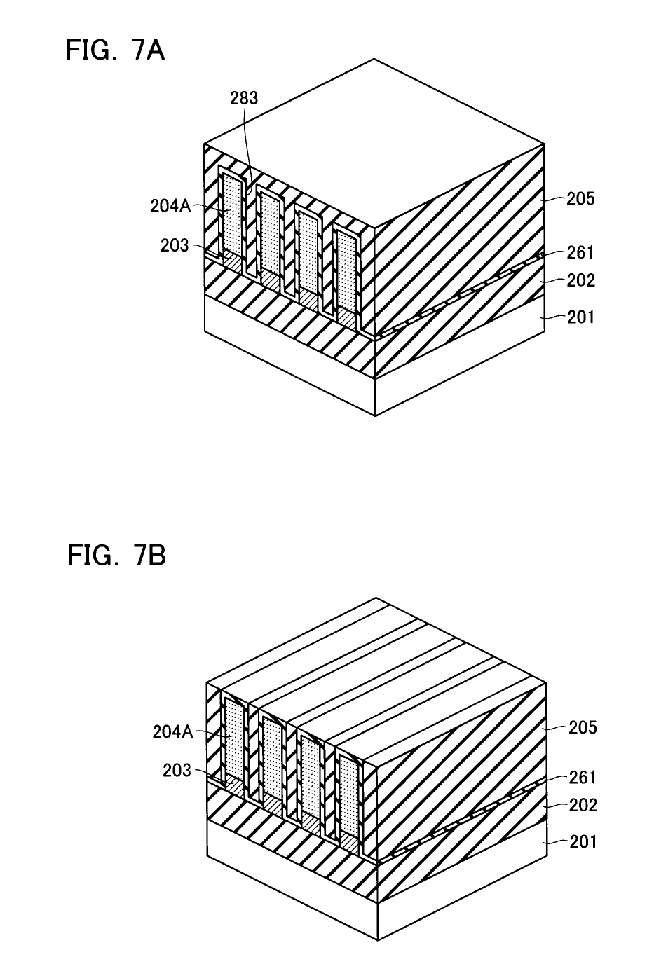

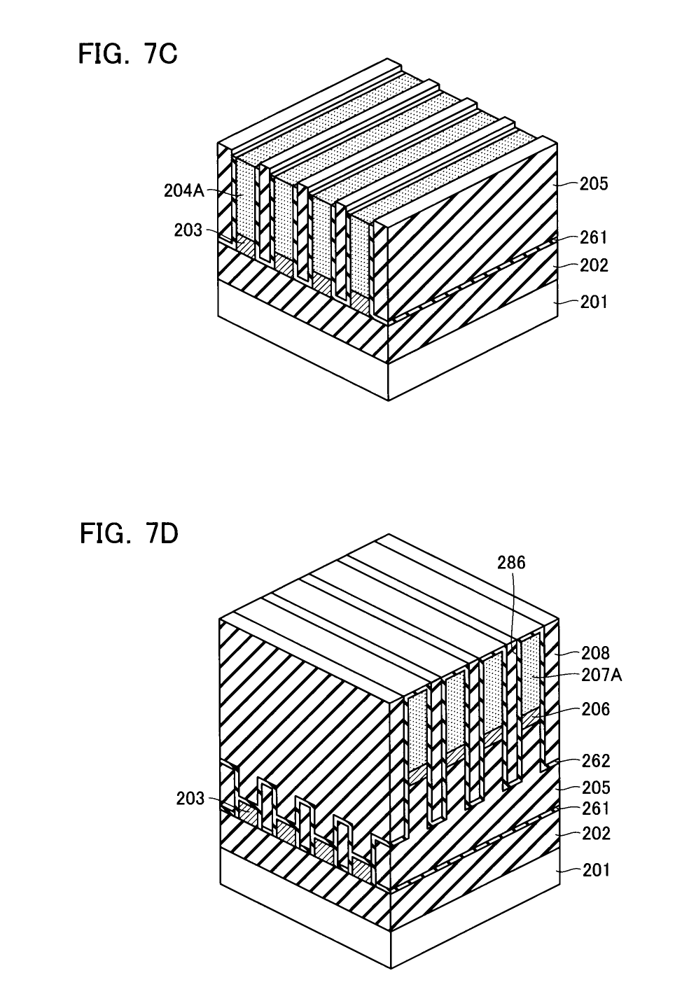

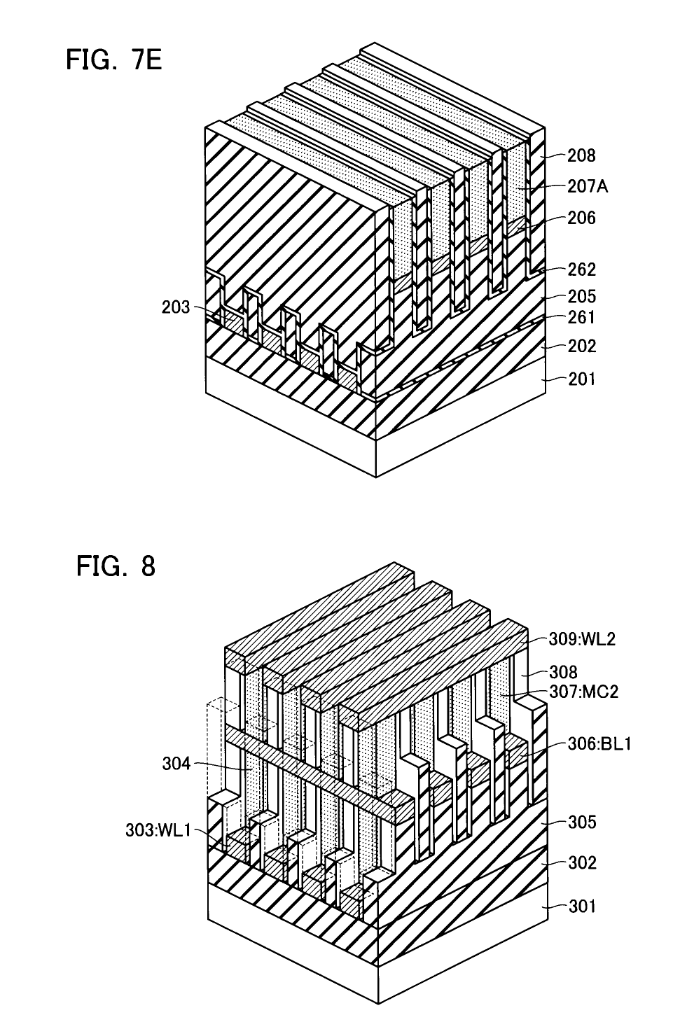

FIG. 7A to FIG. 7E are perspective diagrams showing the steps of manufacturing this memory cell array. No drawing is provided for any steps similar to the steps of manufacturing the memory cell array according to the first embodiment. The semiconductor substrate 101, the insulating layer 102, the word lines 103 and 109, the memory cell layers 104A and 107A, the interlayer insulating films 105 and 108, the bit lines 106, the thin films 161 and 162, and the grooves 183 and 186 shown in FIG. 5A to FIG. 5Q will be explained in the present embodiment as a semiconductor substrate 201, an insulating layer 202, word lines 203 and 209, memory cell layers 204A and 207A, interlayer insulating films 205 and 208, bit lines 206, thin films 261 and 262, and grooves 283 and 286.

First, in the same manner as the first embodiment, a step of forming an insulating layer 202 on a semiconductor substrate 201 to a step of forming a first thin film 261 similar to shown in FIG. 5D are performed.

Then, as shown in FIG. 7A, a first interlayer insulating film 205 made of SiO₂ is deposited on the first thin film 261 until first grooves 283 are filled up.

Then, as shown in FIG. 7B, the top portion of the interlayer insulating film 205 is removed by smoothing the top surface of the interlayer insulating film 205 by CMP or the like until the top surface of the first thin film 261 is exposed.

Then, as shown in FIG. 7C, the top portion of the first thin film 261 is removed by etching until the top surface of the memory cell layer 204A is exposed. As a result, a first stack structure is formed.

Then, in the same manner as shown in FIG. 5F to FIG. 5K of the first embodiment, a step of forming a second interconnection layer to become the bit lines BL1 on the first stack structure to a step of forming a second thin film 262 are performed.

Then, a second interlayer insulating layer 208 made of SiO₂ is deposited on the second thin film 262 until second grooves 286 are filled up. After this, as shown in FIG. 7D, the top portion of the interlayer insulating film 208 is removed by smoothing the top surface of the interlayer insulating film 208 by CMP or the like until the top surface of the second thin film 262 is exposed.

Then, as shown in FIG. 7E, the top portion of the second thin film 262 is removed by etching until the top surface of the memory cell layer 207A is exposed. As a result, a second stack structure is formed.

Then, in the same manner as shown in FIG. 5M to FIG. 5Q of the first embodiment, a step of forming a third interconnection layer to become the word lines WL2 on the second stack structure to a step of forming columnar memory cells MC2 (207) at the intersections of the bit lines BL1 (206) and the word lines WL2 (209) are performed.

Lastly, the memory cell array according to the present embodiment is completed by filling an interlayer insulating film (unillustrated) in the grooves between memory cells MC2 (207) adjoining in the bit line direction.

According to the first embodiment, before the first interlayer insulating film 105 is filled in the first grooves 183, the top portion of the first thin film 161 is removed to expose the top surface of the memory cell layer 104A as shown in FIG. 5E. The present embodiment is different from this in that after the first interlayer insulating film 205 is filled in the first grooves 283, the top portion of the first thin film 261 is removed to expose the top surface of the memory cell layer 204A as shown in FIG. 7C. However, this can as well as the first embodiment remove the regions which adjoin the memory cell layers 204A and 207A and at which there could occur some residue of the memory cell material, with less mask loss.

### THIRD EMBODIMENT

### Structure of Memory Cell Array

FIG. 8 is a perspective diagram showing a part of a memory cell array of a semiconductor memory according to a third embodiment. Portions of the third embodiment that correspond to the portions denoted by reference numerals 101 to 191 of the memory cell array of the first embodiment will be denoted by reference numerals 301 to 391, and redundant explanation about such corresponding portions will not be provided.

The present memory cell array differs from the memory cell array according to the first embodiment shown in FIG. 4A and FIG. 4B in that the first and second thin films are removed in the course of nature.

### Method of Manufacturing Memory Cell Array

Next, a method of manufacturing the memory cell array having a two-layered structure shown in FIG. 8 will be explained.

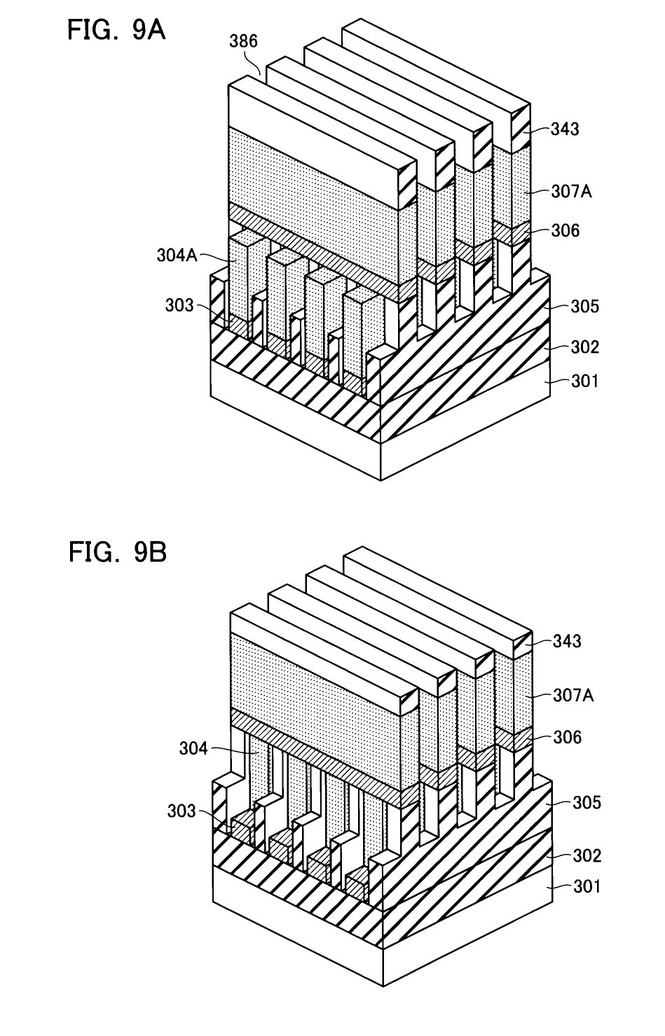

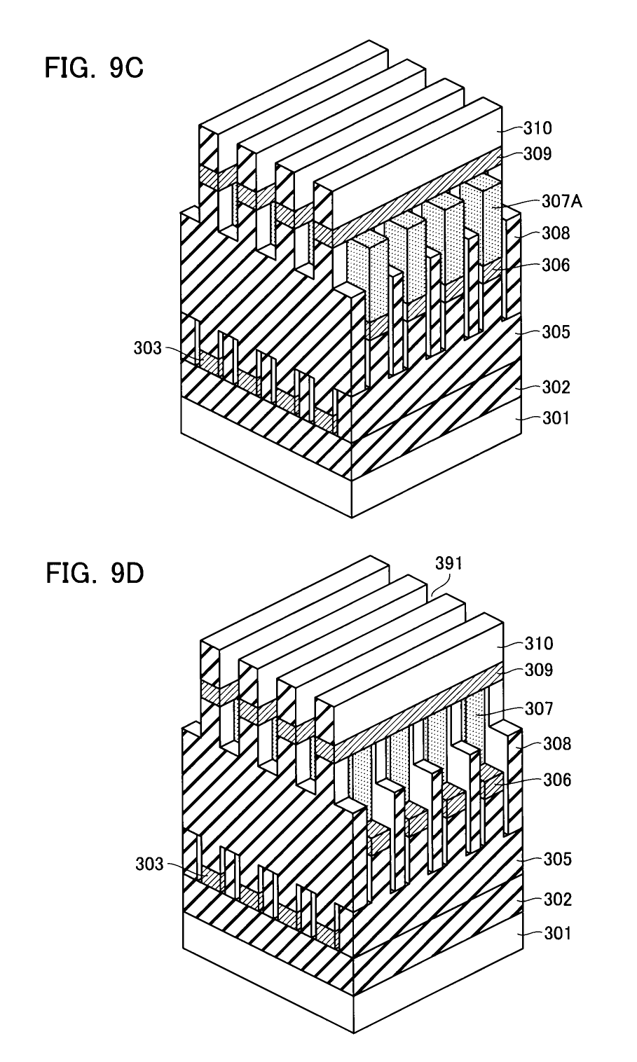

FIG. 9A to FIG. 9D are perspective diagrams showing the steps of manufacturing this memory cell array. No drawing is provided for any steps similar to the steps of manufacturing the memory cell array according to the first embodiment. The first substrate 101, the insulating layers 102 and 110, the word lines 103 and 109, the memory cells 104 and 107, the memory cell layers 104A and 107A, the interlayer insulating films 105 and 108, the bit lines 106, the etching mask 143, the thin films 161 and 162, and the grooves 186 and 191 shown in FIG. 5A to FIG. 5Q will be explained in the present embodiment as a semiconductor substrate 301, insulating layers 302 and 310, word lines 303 and 309, memory cells 304 and 307, memory cell layers 304A and 307A, interlayer insulating films 305 and 308, bit lines 306, an etching mask 343, thin films 361 and 362, and grooves 386 and 391.

First, in the same manner as the first embodiment, a step of forming an insulating layer 302 on a semiconductor substrate 301 to a step of forming second grooves 386 similar to shown in FIG. 5H are performed.

Next, as shown in FIG. 9A, the first thin film 361 is removed by isotropic etching such as wet etching, etc. In this etching step, it is only desired that the first thin film 361 be removed to an extent that no residue occurs from etching the memory cell layer 304A in the next step. However, if the thin film 361 is made of a conductive material such as C (carbon), etc., etching of the thin film 361 is performed until at least the top surface or thereunder of the word lines WL1 (303). Further, since the portions of the first thin film 361 that exist under the bit lines BL1 (306) can also be etched out in this step, a space can be produced between the memory cell layer 304A and the interlayer insulating film 305 under the bit lines BL1 (306), which can reduce parasitic capacitance between adjoining memory cells. After this, the interlayer insulating film 305 is removed selectively by anisotropic etching such as RIE, etc. using the etching mask 343 as a mask. Anisotropic etching on the interlayer insulating film 305 may be skipped if the interlayer insulating film 305 does not much influence anisotropic etching on the memory cell layer 304A.

Then, as shown in FIG. 9B, in the same manner as the first embodiment, the memory cell layer 304A is removed selectively by anisotropic etching such as RIE, etc. using the etching mask 343 as a mask. As a result, columnar memory cells MC1 (304) are formed at the intersections of the word lines WL1 (303) and the bit lines BL1 (306). After this, the etching mask 343 is stripped.

Then, in the same manner as shown in FIG. 5K to FIG. 5O of the first embodiment, a step of forming a second thin film 362 to a step of forming grooves which reach the bottom surface of the word lines WL2 (309) are performed.

Then, as shown in FIG. 9C, the second thin film 362 is removed by isotropic etching such as wet etching, etc. In this etching, it is only desired that the thin film 362 be removed to an extent that no residue occurs from etching the memory cell layer 307A in the next step. However, if the thin film 362 is made of a conductive material such as C (carbon), etc., etching of the thin film 362 is performed until at least the top surface or thereunder of the word lines WL1 (303). Further, since the portions of the second thin film 362 that exist under the word lines WL2 (309) can also be etched out in this step, a space can be produced between the memory cell layer 307A and the interlayer insulating film 308 under the word lines WL2 (309), which can reduce parasitic capacitance between adjoining memory cells. After this, the interlayer insulating film 308 is removed selectively by anisotropic etching such as RIE, etc. using the insulating layer 310 as a mask. Anisotropic etching on the interlayer insulating film 308 may be skipped if the interlayer insulating film 308 does not much influence anisotropic etching on the memory cell layer 307A.

Then, as shown in FIG. 9D, the memory cell layer 307A is removed selectively by anisotropic etching such as RIE, etc. using the insulating layer 310 as a mask. As a result, columnar memory cells MC2 (307) are formed at the intersections of the bit lines BL1 (306) and the word lines WL2 (309), and the memory cell array shown in FIG. 8 is formed.

Lastly, the memory cell array according to the present embodiment is completed by filling an interlayer insulating film (unillustrated) in the grooves 391 between memory cells MC2 (307) adjoining in the bit line direction.

According to the present embodiment, the first and second thin films 361 and 362 are removed isotropically. Therefore, the first and second thin films 361 and 362 can be made of a conductive material. In this case too, like the first embodiment, it is possible to provide a semiconductor memory which includes no residue of the memory cell material between adjoining memory cells with less mask loss in etching.

Though it might be feared that removing the thin films sacrifices the physical strength of the memory cell array, this will not be a significant problem because large part of the space between the memory cells is occupied by the interlayer insulating film.

### OTHER EMBODIMENTS

While certain embodiments have been described, these embodiments have been presented by way of example only, and are not intended to limit the scope of the inventions. Indeed, the novel methods and systems described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

The first to third embodiments have explained a method of manufacturing a memory cell array having a two-layered structure. However, it is possible to form a cross-point type memory cell array including an arbitrary number of layers, by repeating the formation of the stack structure described above. Conversely, when manufacturing a single-layered memory cell array, the formation of the upper-layer memory cell material should be skipped.

The present invention is not limited in terms of memory cell structure, and hence can be applied to various cross-point type semiconductor memory devices such as a phase change memory element, an MRAM element, a PRRAM, a ReRAM, etc.

What is claimed is:

1. A method of manufacturing a semiconductor memory device, comprising:
forming a first interconnection layer above a semiconductor substrate;
forming a first memory cell layer to constitute first memory cells above the first interconnection layer;
after forming the first memory cell layer, forming first lines by forming first grooves deep to a bottom of the first interconnection layer and extending in a first direction;
forming a first thin film on side walls of the first grooves;
forming a first stack structure by filling a first interlayer insulating film in the first grooves having the first thin film formed thereon;
forming a second interconnection layer above the first stack structure;
forming second lines by forming second grooves deep to a bottom of the second interconnection layer and extending in a second direction intersecting with the first direction;
removing the first thin film exposed at a bottom of the second grooves; and
forming the first memory cells having a columnar shape by removing the first memory cell layer exposed at the bottom of the second grooves,
the first thin film having a higher etching rate than that of the first interlayer insulating film, the first thin film being removed prior to removing those portions of the first memory cell layer that adjoin the first thin film.

2. The method of manufacturing the semiconductor memory device according to claim 1, further comprising:
after forming the second interconnection layer and before forming the second lines, forming a second memory cell layer to constitute second memory cells above the second interconnection layer, and then forming the second grooves also in the second memory cell layer;
after forming the first memory cells, forming a second thin film on side walls of the second grooves;
forming a second stack structure by filling a second interlayer insulating film in the second grooves having the second thin film formed thereon;
forming a third interconnection layer above the second stack structure;
forming third lines by forming third grooves deep to a bottom of the third interconnection layer and extending in the first direction;
removing the second thin film exposed at a bottom of the third grooves; and
forming the second memory cells having a columnar shape by removing the second memory cell layer exposed at the bottom of the third grooves,
wherein the second thin film has a higher etching rate than that of the second interlayer insulating film, and is removed prior to removing those portions of the second memory cell layer that adjoin the second thin film.

3. The method of manufacturing the semiconductor memory device according to claim 1,
wherein forming the first thin film includes:
depositing the first thin film on a top surface of the first memory cell layer and on the side walls and a bottom of the first grooves; and
removing the first thin film except those portions formed on the side walls of the first grooves.

4. The method of manufacturing the semiconductor memory device according to claim 1,
wherein forming the first thin film includes depositing the first thin film on a top surface of the first memory cell layer and on the side walls and a bottom of the first grooves, and
wherein forming the first stack structure includes:
filling the first interlayer insulating film in the first grooves having the first thin film formed thereon;
removing a top portion of the first interlayer insulating film until a top surface of the first thin film is exposed; and
removing a top portion of the first thin film until the first memory cell layer is exposed.

5. The method of manufacturing the semiconductor memory device according to claim 1,
wherein removing the first thin film includes recessing the first thin film at the bottom of the second grooves until a top surface of the first thin film comes to a height of at least a top surface or thereunder of the first lines.

6. The method of manufacturing the semiconductor memory device according to claim 1,
wherein when removing the first thin film, the first thin film is removed anisotropically.

7. The method of manufacturing the semiconductor memory device according to claim 1,
wherein when removing the first thin film, the first thin film is removed isotropically.

8. The method of manufacturing the semiconductor memory device according to claim 1,
wherein a material of the first thin film includes any of SiN, SiO₂, Al₂O₃, CVD-C, SiC, BN, and SiOC.

9. The method of manufacturing the semiconductor memory device according to claim 1,
wherein the first thin film is a porous film.

10. A method of manufacturing a semiconductor memory device, comprising:
forming a first interconnection layer above a semiconductor substrate;
forming a first memory cell layer to constitute first memory cells above the first interconnection layer;
after forming the first memory cell layer, forming first lines by forming first grooves deep to a bottom of the first interconnection layer and extending in a first direction;
forming a first thin film on side walls of the first grooves;
forming a first stack structure by filling a first interlayer insulating film in the first grooves having the first thin film formed thereon;
forming a second interconnection layer above the first stack structure;
forming second lines by forming second grooves deep to a bottom of the second interconnection layer and extending in a second direction intersecting with the first direction;
preferentially removing the first thin film exposed at a bottom of the second grooves; and
after preferentially removing the first thin film, removing the first memory cell layer exposed at the bottom of the second grooves, thereby forming the first memory cells having a columnar shape.

11. The method of manufacturing the semiconductor memory device according to claim 10, further comprising:
after forming the second interconnection layer and before forming the second lines, forming a second memory cell layer to constitute second memory cells above the second interconnection layer, and then forming the second grooves also in the second memory cell layer;
after forming the first memory cells, forming a second thin film on side walls of the second grooves;
forming a second stack structure by filling a second interlayer insulating film in the second grooves having the second thin film formed thereon;
forming a third interconnection layer above the second stack structure;
forming third lines by forming third grooves deep to a bottom of the third interconnection layer and extending in the first direction;
preferentially removing the second thin film exposed at a bottom of the third grooves; and
after preferentially removing the second thin film, removing the second memory cell layer exposed at the bottom of the third grooves, thereby forming the second memory cells having a columnar shape.

12. The method of manufacturing the semiconductor memory device according to claim 10,
wherein forming the first thin film includes:
depositing the first thin film on a top surface of the first memory cell layer and on the side walls and a bottom of the first grooves; and
removing the first thin film except those portions formed on the side walls of the first grooves.

13. The method of manufacturing the semiconductor memory device according to claim 10,
wherein forming the first thin film includes depositing the first thin film on a top surface of the first memory cell layer and on the side walls and a bottom of the first grooves, and
wherein forming the first stack structure includes:
filling the first interlayer insulating film in the first grooves having the first thin film formed thereon;
removing a top portion of the first interlayer insulating film until a top surface of the first thin film is exposed; and
removing a top portion of the first thin film until the first memory cell layer is exposed.

14. The method of manufacturing the semiconductor memory device according to claim 10,
wherein preferentially removing the first thin film includes recessing the first thin film at the bottom of the second grooves until a top surface of the first thin film comes to a height of at least a top surface or thereunder of the first lines.

15. The method of manufacturing the semiconductor memory device according to claim 10,
wherein when preferentially removing the first thin film, the first thin film is removed anisotropically.

16. The method of manufacturing the semiconductor memory device according to claim 10,
wherein when preferentially removing the first thin film, the first thin film is removed isotropically.

17. The method of manufacturing the semiconductor memory device according to claim 10,
wherein a material of the first thin film includes any of SiN, SiO₂, Al₂O₃, CVD-C, SiC, BN, and SiOC.

18. The method of manufacturing the semiconductor memory device according to claim 10,
wherein the first thin film is a porous film.

19. A semiconductor memory device, comprising:
a plurality of first lines extending in a first direction;
a plurality of second lines extending in a second direction intersecting with the first direction;
a plurality of columnar memory cells connected between the first and second lines at intersections of the first and second lines; and
an interlayer insulating film provided between adjoining ones of the memory cells,
a space being provided between each of the memory cells and the interlayer insulating film.

20. The semiconductor memory device according to claim 19, wherein plural stacked layers are provided each including a structure composed of the columnar memory cells connected between the first and second lines at the intersections of the first and second lines.
